(19) United States
(12) Patent Application Publication
(10) Pub. No.: US 2025/0221078 A1
(43) Pub. Date: Jul. 3, 2025

(54) IMAGE SENSING ASSEMBLY AND SMART GLASSES

(71) Applicants: Asphetek Solution (Chengdu) Ltd., Chengdu (CN); ADVANCED OPTOELECTRONICS TECHNOLOGY, INC., Hsinchu County (TW); Asphetek Solution Inc., Hsinchu (TW)

(72) Inventors: YUAN-TING LIANG, Hsinchu (TW); CHUNG-WU LIU, Hsinchu (TW)

(21) Appl. No.: 18/943,051

(22) Filed: Nov. 11, 2024

(30) Foreign Application Priority Data
Jan. 3, 2024 (CN) 202420009466.7

(51) Int. Cl. H01L 27/146; G02B 27/01; G02C 11/00; G06F 3/01

(52) U.S. Cl. CPC H10F 39/809; G02C 11/10; H10F 39/804; H10F 39/806; H10F 39/8063; H10F 39/811; G02B 27/0179; G02B 2027/0187; G06F 3/013

(57) ABSTRACT

An image sensing assembly includes a first image sensing part arranged at a first side of the first sensing chip; a second sensing chip stacked at a second side of the first sensing chip, the second side being away from the first image sensing part; a second image sensing part arranged at a third side of the second sensing chip, the third side being away from the first sensing chip; and a circuit board arranged at the first side of the first sensing chip, the first side being away from the second sensing chip, wherein the circuit board defines a through groove, the first sensing chip is disposed on the circuit board, the first image sensing part corresponds to the through groove, the circuit board is electrically connected to the first sensing chip and the second sensing chip.

### FIELD

The present application relates to the technical field of image sensing, and in particular to an image sensing assembly and a pair of smart glasses.

### BACKGROUND

Eye tracking and environment recognition are often included in the functions of augmented reality/simulated reality smart glasses. To achieve eye tracking and environment recognition, at least two image sensing devices are usually independently set on the smart glasses to detect internal and external image information, respectively. However, two independently set image sensing devices occupy more installation space, resulting in an increase in size of the smart glasses, which is not conducive to the trends of thinner and lighter smart glasses.

### SUMMARY

An embodiment of the present application provides an image sensing assembly, including a first sensing chip, a first image sensing part, a second sensing part, a second image sensing part and a circuit board. The first image sensing part is arranged at a first side of the first sensing chip. The second sensing part is stacked at a second side of the first sensing chip away from the first image sensing part. The second image sensing part is arranged at a third side of the second sensing chip away from the first sensing chip. The circuit board is arranged at the first side of the first sensing chip away from the second sensing chip, the circuit board defines a through groove, the first sensing chip is arranged on the circuit board, the first image sensing part corresponds to the through groove, the circuit board is electrically connected to the first sensing chip, the circuit board is electrically connected to the second sensing chip.

In the present application, the first sensing chip and the second sensing chip are stacked to each other, the first image sensing part and the second image sensing part are set opposite to each other, the through groove corresponds to the first image sensing part and the second image sensing part, this simplifies sensing structure on both sides of the image sensing assembly, and the image sensing assembly can realize image sensing on two opposite sides of the image sensing assembly at the same time, reducing volume of the image sensing assembly, reducing installation space occupied by the image sensing assembly in a pair of smart glasses, this is conducive to thin and light development of the smart glasses.

### BRIEF DESCRIPTION OF THE DRAWINGS

FIG. 1 is a schematic drawing of an image sensing assembly according to an embodiment of the present disclosure.

FIG. 2 is a schematic drawing of a pair of smart glasses according to an

embodiment of the present disclosure.

### DETAILED DESCRIPTION

In order to make the above-mentioned objects, features and advantages of the present application more obvious, a detailed description of specific embodiments of the present application will be described in detail with reference to the accompanying drawings. A number of details are set forth in the following description so as to fully understand the present application. However, the present application can be implemented in many other ways different from those described herein, and those skilled in the art can make similar improvements without violating the contents of the present application. Therefore, the present application is not to be considered as limiting the scope of the embodiments described herein.

Several definitions that apply throughout this disclosure will now be presented.

The term “coupled” is defined as coupled, whether directly or indirectly through intervening components, and is not necessarily limited to physical connections. The connection may be such that the objects are permanently coupled or releasably coupled. The term “substantially” is defined to be essentially conforming to the particular dimension, shape, or other feature that the term modifies, such that the component need not have that exact feature. The term “comprising,” when utilized, means “including, but not necessarily limited to;” it specifically indicates open-ended inclusion or membership in the so-described combination, group, series, and the like.

Unless otherwise defined, all technical and scientific terms used herein have the same meaning as commonly understood by one skilled in the art. The terms used in a specification of the present application herein are only for describing specific embodiments and are not intended to limit the present application. The terms “and/or” used herein includes any and all combinations of one or more of associated listed items.

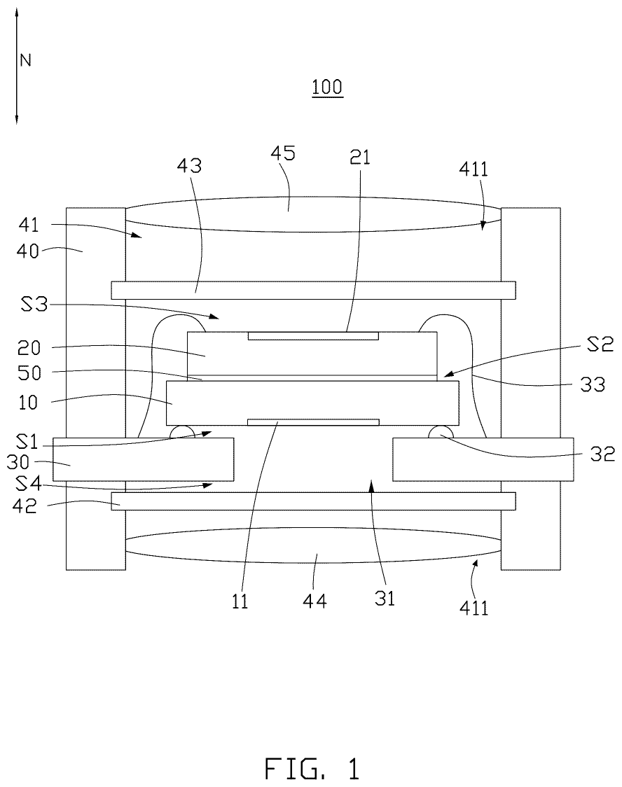

Referring to FIG. 1, an image sensing assembly 100 is disclosed in one embodiment. The image sensing assembly 100 includes a first sensing chip 10, a second sensing chip 20 and a circuit board 30. A first image sensing part 11 is arranged at a first side S1 of the first sensing chip 10. The second sensing chip 20 is stacked at a second side S2 of the first sensing chip 10, the second side S2 being away from the first image sensing part 11. The second image sensing part 21 is arranged at a third side S3 of the second sensing chip 20, the third side S3 being away from the first sensing chip 10. The circuit board 30 is arranged at the first side S1 of the first sensing chip 10, the first side S1 being away from the second sensing chip 20, the circuit board 30 defines a through groove 31, the first sensing chip 10 is disposed on the circuit board 30, the first image sensing part 11 corresponds to the through groove 31, the circuit board 30 is electrically connected to the first sensing chip 10 and the second sensing chip 20.

In the present application, the first sensing chip 10 and the second sensing chip 20 are stacked to each other, the first image sensing part 11 and the second image sensing part 21 are set opposite to each other, the through groove 31 corresponds to the first image sensing part 11 and the second image sensing part 21, this simplifies sensing structure on both sides of the image sensing assembly 100, and the image sensing assembly 100 can realize image sensing on two opposite sides of the image sensing assembly 100 at the same time, reducing volume of the image sensing assembly 100, reducing installation space occupied by the image sensing assembly 100 in a pair of smart glasses 200, this is conducive to thin and light development of the smart glasses 200.

In one embodiment, the first image sensing part 11 faces to the circuit board 30, and the first image sensing part 11 corresponds to the through groove 31. The first sensing chip 10 is fixed on the circuit board 30 in form of crystal encapsulation and connects to circuit, this realizes the first sensing chip 10 electrically connects to the circuit board 30.

In one embodiment, the image sensing assembly 100 further includes a plurality of pads 32, the plurality of pads 32 is disposed on the circuit board 30, the plurality of pads 32 is distributed on a peripheral of the through groove 31, the first sensing chip 10 is arranged on the plurality of pads 32, and is connected to the plurality of pads 32, the first sensing chip 10 is electrically connected to the circuit board 30 via the plurality of pads 32.

In one embodiment, the image sensing assembly 100 further includes conductive wire 33, the conductive wire 33 is disposed on the circuit board 30, the conductive wire 33 is electrically connected between the second sensing chip 20 and the circuit board 30. Quantity of the conductive wire 33 is multiple, a plurality of conductive wires 33 is spaced apart along edge of the first sensing chip 10 and edge of the second sensing chip 20. A line diameter of the conductive wire 33 is between 1 um to 100 um. Material of the conductive wire 33 includes but is not limited to gold, silver, copper, aluminum and other conductive materials.

In other embodiment, the second sensing chip 20 is electrically connected to the first sensing chip 10, and the second sensing chip 20 is electrically connected to the circuit board 30 via the first sensing chip 10.

In one embodiment, the circuit board 30 may be printed circuit board 30 or flexible circuit board 30. A thickness of the circuit board 30 is between 10 um to 3 mm. The through groove 31 is coaxial with the first image sensing part 11, a projected area of an orthographic projection of the through groove 31 on the first sensing chip 10 along an axial direction N of the through groove 31 is large than an area of the first image sensing part 11, avoiding the circuit board 30 overshadows the first image sensing part 11. A shape of the through groove 31 may be Circle, rectangle or polygon.

In one embodiment, a caliber of the through groove 31 is between 1 mm to 1 cm. In one embodiment, a width of the through groove 31 is between 1 mm to 1 cm, a length of the through groove 31 is between 1 mm to 1 cm, this meet sensing requirements of the first image sensing part 11.

In one embodiment, the first sensing chip 10 may be CCD or CMOS, a width of the first sensing chip 10 is between 1 mm to 3 cm, a length of the first sensing chip 10 is between 1 mm to 3 cm, a second thickness of the first sensing chip 10 is between 50 um to 1000 um, a spectral response range of the first sensing chip 10 is between 400 nm to 1000 nm. The second sensing chip 20 may be the same type as the first sensing chip 10.

In one embodiment, a sectional dimension of the second sensing chip 20 is smaller than or equal to a sectional dimension of the first sensing chip 10, making it easy to distinguish the first sensing chip 10 and the second sensing chip 20, reducing assembly difficulty of the first sensing chip 10 and the second sensing chip 20.

In one embodiment, the image sensing assembly 100 further includes a bonding layer 50, the bonding layer 50 is positioned between the first sensing chip 10 and the second sensing chip 20, and the bonding layer 50 is bonded to the first sensing chip 10 and the second sensing chip 20, so that the first sensing chip 10 is opposite to the second sensing chip 20, and positions of the first sensing chip 10 and the second sensing chip 20 are relatively fixed.

In one embodiment, materials of the bonding layer 50 may be resin, silicone, polyimide or cyanoacrylate. After the first sensing chip 10 and the second sensing chip 20 are bonded and fixed via the bonding layer 50, a distance between outer surface of the first image sensing part 11 and outer surface of the second image sensing part 21 is between 1 um to 100 um, that is, an overall thickness of the first sensing chip 10, the second sensing chip 20 and the bonding layer is between 1 um to 100 um.

In one embodiment, the image sensing assembly 100 further includes a shell 40, the shell 40 defines a mounting cavity 41, each ends of the mounting cavity 41 defines an opening 411, the first sensing chip 10, the second sensing chip 20 and the circuit board 30 are received in the mounting cavity 41, sides of the circuit board 30 are connected with inner walls of the mounting cavity 41. The first image sensing part 11 of the first sensing chip 10 facing the opening 411 located below the mounting cavity 41, the second image sensing part 21 of the second sensing chip 20 facing the opening 411 located above the mounting cavity 41.

In one embodiment, the image sensing assembly 100 further includes first filter 42 and second filter 43. The first filter 42 is arranged at a fourth side S4 of the circuit board 30 away from the first sensing chip 10, the first filter 42 covers the through groove 31, and the first filter 42 is separated from the circuit board 30. The first filter 42 is configured to filter light having wavelengths outside of a target wave band, reducing interference to image and improving detection accuracy of the first sensing chip 10.

The second filter 43 is arranged at the third side S3 of the second sensing chip 20 away from the first sensing chip 10, the second filter 43 covers the through groove 31, and the second filter 43 is separated from the circuit board 30. The second filter 43 is configured to filter light having wavelengths outside of other target wave band, improving detection accuracy of the second sensing chip 20.

Edges of the first filter 42 and the second filter 43 are connected with the inner walls of the mounting cavity 41, the first filter 42 and the second filter 43 fully covers inner section of the mounting cavity 41, thereby reducing stray light entering the first filter 42 and the second filter 43.

In one embodiment, the first filter 42 is infrared light filter, the second filter 43 is infrared light filter.

In one embodiment, the image sensing assembly 100 further includes first optical lens 44 and second optical lens 45. The first optical lens 44 is arranged in the shell 40 and the second optical lens 45 is arranged in the shell 40.

The first optical lens 44 is arranged at the fourth side S4 of the circuit board 30 away from the first sensing chip 10, the first optical lens 44 is connected with the inner walls of the mounting cavity 41. The first optical lens 44 is arranged at the opening 411 located below the mounting cavity 41, and the first optical lens 44 is configured to focus external light on the first sensing chip 10.

The second optical lens 45 is arranged at the third side S3 of the second sensing chip 20 away from the first sensing chip 10, the second optical lens 45 is connected with the inner walls of the mounting cavity 41. The second optical lens 45 is arranged at the opening 411 located above the mounting cavity 41, and the second optical lens 45 is configured to focus the external light on the second sensing chip 20.

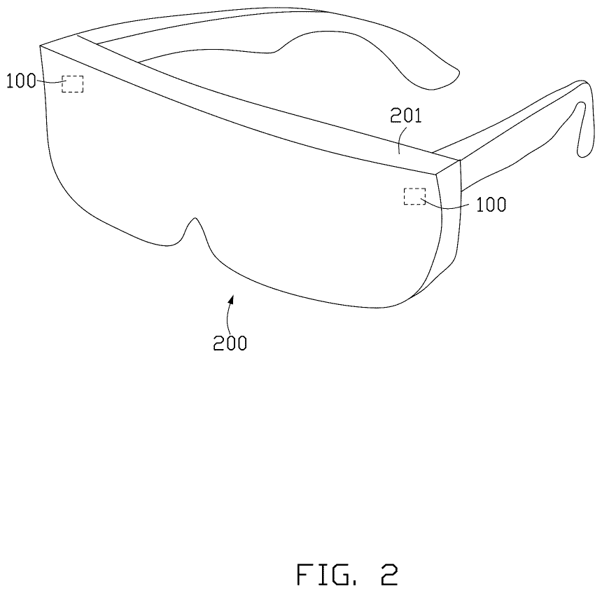

Referring to FIG. 2, an embodiment of the present application also provides a pair of smart glasses 200. The smart glasses 200 includes a glasses frame 201 and the above-mentioned image sensing assembly 100, the image sensing assembly 100 is installed in the glasses frame 201. The image sensing assembly 100 is configured to measure movement image information of eyeball on inside of the glasses frame 201 and external environment image information of the glasses frame 201.

In one embodiment, a quantity of the image sensing assembly 100 is two, the two image sensing assemblies 100 are disposed on opposite sides of the glasses frame 201, the two image sensing assemblies 100 are configured to measure movement of two eyeballs, and the two image sensing assemblies 100 are configured to measure the external environment image information of left side and right side of the glasses frame 201.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. An image sensing assembly comprising:
a first sensing chip;
a first image sensing part arranged at a first side of the first sensing chip;
a second sensing chip stacked at a second side of the first sensing chip, the second side being away from the first image sensing part;
a second image sensing part arranged at a third side of the second sensing chip, the third side being away from the first sensing chip; and
a circuit board arranged at the first side of the first sensing chip, the first side being away from the second sensing chip, wherein the circuit board defines a through groove, the first sensing chip is disposed on the circuit board, the first image sensing part corresponds to the through groove, the circuit board is electrically connected to the first sensing chip and the second sensing chip.

2. The image sensing assembly as claimed in claim 1, wherein the through groove is coaxial with the first image sensing part, a projected area of an orthographic projection of the through groove on the first sensing chip along an axial direction of the through groove is large than an area of the first image sensing part.

3. The image sensing assembly as claimed in claim 1, wherein a caliber of the through groove is between 1 mm to 1 cm.

4. The image sensing assembly as claimed in claim 1, further comprising a bonding layer positioned between the first sensing chip and the second sensing chip, and the bonding layer is bonded to the first sensing chip and the second sensing chip.

5. The image sensing assembly as claimed in claim 1, wherein a sectional dimension of the second sensing chip is smaller than or equal to a sectional dimension of the first sensing chip.

6. The image sensing assembly as claimed in claim 1, further comprising a shell, wherein the shell defines a mounting cavity, each end of the mounting cavity defines an opening, the first sensing chip, the second sensing chip and the circuit board are received in the mounting cavity, sides of the circuit board are connected with inner walls of the mounting cavity.

7. The image sensing assembly as claimed in claim 6, further comprising a shim; first optical lens; and second optical lens, wherein the first optical lens is arranged in the shell; the second optical lens is arranged in the shell, the first optical lens is arranged at a fourth side of the circuit board away from the first sensing chip, and is connected with the inner walls of the mounting cavity, the second optical lens is arranged at the third side of the second sensing chip away from the first sensing chip, and is connected with the inner walls of the mounting cavity.

8. The image sensing assembly as claimed in claim 1, further comprising a plurality of pads and a conductive wire, wherein the plurality of pads is disposed on the circuit board, the plurality of pads is connected to the first sensing chip; and
the conductive wire is disposed on the circuit board and electrically connected between the second sensing chip and the circuit board.

9. The image sensing assembly as claimed in claim 8, wherein, a line diameter of the conductive wire is between 1 um to 100 um.

10. The image sensing assembly as claimed in claim 8, wherein the plurality of pads is distributed on a peripheral of the through groove.

11. The image sensing assembly as claimed in claim 1, further comprising a first filter and a second filter, wherein the first filter is arranged at a fourth side of the circuit board away from the first sensing chip, the first filter covers the through groove, and the first filter is separated from the circuit board and is configured to filter light having wavelengths outside of a target wave band;
the second filter is arranged at the third side of the second sensing chip away from the first sensing chip, the second filter covers the through groove, and the second filter is separated from the circuit board, and is configured to filter light having wavelengths outside of another target wave band.

12. The image sensing assembly as claimed in claim 11, wherein the shell defines a mounting cavity, edges of the first filter and the second filter are connected with an inner wall of the mounting cavity, the first filter and the second filter fully covers an inner section of the mounting cavity.

13. A pair of smart glasses comprising:
a glasses frame; and
an image sensing assembly arranged in the glasses frame, wherein the image sensing assembly comprises:
a first sensing chip;
a first image sensing part arranged at a first side of the first sensing chip;
a second sensing chip stacked at a second side of the first sensing chip, the second side being away from the first image sensing part;
a second image sensing part arranged at a third side of the second sensing chip, the third side being away from the first sensing chip; and
a circuit board arranged at the first side of the first sensing chip, the first side being away from the second sensing chip, wherein the circuit board defines a through groove, the first sensing chip is disposed on the circuit board, the first image sensing part corresponds to the through groove, the circuit board is electrically connected to the first sensing chip and the second sensing chip.

14. The smart glasses as claimed in claim 13, wherein, the through groove is coaxial with the first image sensing part, a projected area of an orthographic projection of the through groove on the first sensing chip along an axial direction of the through groove is large than an area of the first image sensing part.

15. The smart glasses as claimed in claim 13, wherein, a caliber of the through groove is between 1 mm to 1 cm.

16. The smart glasses as claimed in claim 13, further comprising a bonding layer, positioned between the first sensing chip and the second sensing chip and the bonding layer is bonded to the first sensing chip and the second sensing chip.

17. The smart glasses as claimed in claim 13, wherein, a sectional dimension of the second sensing chip is smaller than or equal to a sectional dimension of the first sensing chip.

18. The smart glasses as claimed in claim 13, further comprising a shell, wherein the shell defines a mounting cavity, each end of the mounting cavity defines an opening, the first sensing chip, the second sensing chip and the circuit board are received in the mounting cavity, sides of the circuit board are connected with inner walls of the mounting cavity.

19. The smart glasses as claimed in claim 18, further comprising a shim, first optical lens; and second optical lens, wherein the first optical lens is arranged in the shell; the second optical lens is arranged in the shell, the first optical lens is arranged at a fourth side of the circuit board away from the first sensing chip, and is connected with the inner walls of the mounting cavity, the second optical lens is arranged at the third side of the second sensing chip away from the first sensing chip, and is connected with the inner walls of the mounting cavity.

20. The smart glasses as claimed in claim 13, further comprising a plurality of pads and a conductive wire, wherein the plurality of pads is disposed on the circuit board, the plurality of pads is connected to the first sensing chip; and
the conductive wire is disposed on the circuit board and electrically connected between the second sensing chip and the circuit board.
